(19) United States
(12) Patent Application Publication
(10) Pub. No.: US 2026/0299007 A1
(43) Pub. Date: Oct. 1, 2026

(54) PROGRAMMABLE COMPENSATING PROBE ATTACHMENT TO NEUTRALIZE SHUNT PARASITIC EFFECTS

(71) Applicant: Tektronix, Inc., Beaverton, OR (US)

(72) Inventors: Daniel G. Knierim, Beaverton, OR (US); Julie A. Campbell, Beaverton, OR (US); Matthew Hull, Beaverton, OR (US); Brittany Taggart, Beaverton, OR (US); Daniel D. Schaeffer, Minneapolis, MN (US)

(21) Appl. No.: 19/570,110

(22) Filed: Mar. 17, 2026

Related U.S. Application Data
(60) Provisional application No. 63/773,168, filed on Mar. 17, 2025.

(51) Int. Cl. G01R 31/28

(52) U.S. Cl. CPC G01R 31/2806

(57) ABSTRACT

In some implementations, a device may include a first connection interface structured to receive an uncompensated measurement signal from a shunt on a device under test (DUT). In addition, the device may include one or more adjustable compensation elements in a compensation circuit, the one or more adjustable compensation elements configured to produce a compensated measurement signal by adjusting a frequency response pole of the compensation circuit to compensate for an inductance of the shunt. The device may include a second connection interface structured to output the compensated measurement signal to the test and measurement probe. A test and measurement system includes a test and measurement instrument, a shunt, a compensating circuit, and a test and measurement probe.

### CROSS-REFERENCE TO RELATED APPLICATIONS

This application is a non-provisional of, and claims priority to, U.S. Prov. Pat. App. No. 63/773,168, filed Mar. 17, 2025, the contents of which are hereby incorporated by reference into this disclosure.

### TECHNICAL FIELD

This disclosure relates to test and measurement instruments, and more particularly to a probe attachment for a test and measurement instrument.

### BACKGROUND

Generally, current shunts, when placed into a circuit of a device under test (DUT), e.g. a printed circuit board (PCB), have an inherent inductive property that becomes more prevalent at high frequencies.

FIG. 1 is a graph 100 illustrating the frequency response of an uncompensated shunt 110, i.e. a current shunt without a compensating pole circuit, versus the frequency response of a compensated shunt 120, i.e. a current shunt with a compensating pole in the circuit. As seen in FIG. 1, the frequency response of the uncompensated shunt 110 is not flat, and increases at higher frequencies, while the frequency response of the compensated shunt 1120 is generally flat across a wide range of frequencies.

Usually this self inductance problem is solved by placing a “compensating pole” in the form of a resistor and capacitor (“RC”) or an inductor and resistor (“L over R”) filter in line with the measurement probing point. However, this solution is only possible if the DUT has been purposefully designed to include a current shunt. These pole designs are built into the DUT board with a fixed shunt value and geometry in mind. However, there is no existing solution for a DUT that was not designed to include a current shunt, and therefore not designed to include a compensating pole in the circuit with the shunt, nor is there any existing general purpose solution that can work with shunts of various values.

### BRIEF DESCRIPTION OF THE DRAWINGS

FIG. 1 is a graph illustrating the frequency response of an uncompensated versus a compensated shunt.

FIG. 2 is block diagram of a testing system 200 according to embodiments of the disclosure.

FIG. 3 is a perspective view of a probe tip and compensator device, according to an example embodiment of the disclosure.

FIG. 4 is a view of a printed circuit board layout according to an example embodiment of the disclosure.

FIG. 5 is a graph illustrating three time domain responses of a compensator, according to embodiments of the disclosure.

FIG. 6 is a table of known off the shelf shunt values and associated compensator settings, according to embodiments of the disclosure.

FIG. 7 is a table of known custom shunt values and associated compensator settings, according to embodiments of the disclosure.

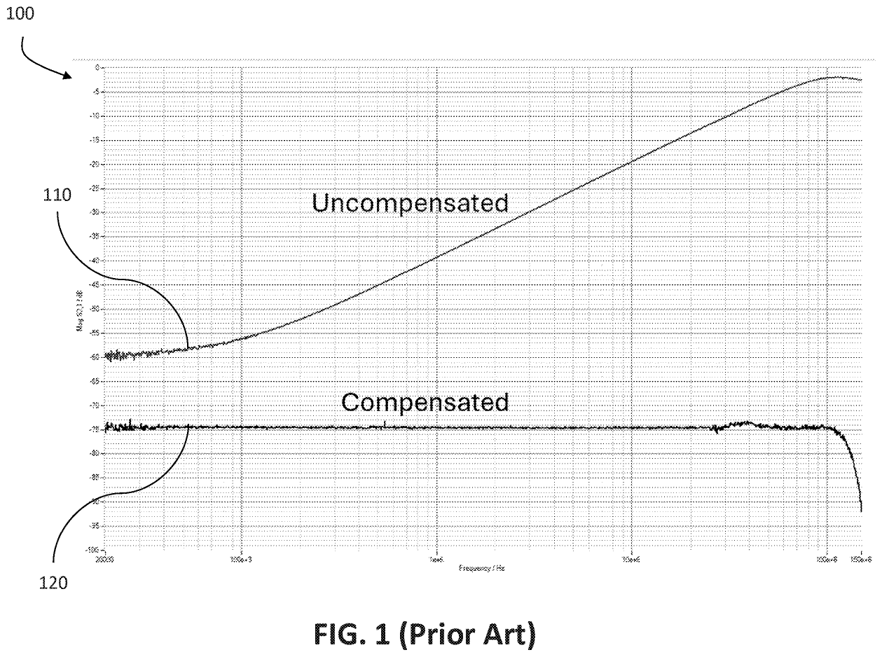

### DETAILED DESCRIPTION

The present disclosure describes a device placed in between the current shunt and a probe, and the device includes digitally programmable components that can compensate for the inductive effects of the presence of a shunt by tuning the compensating pole value for more accurate measurements.

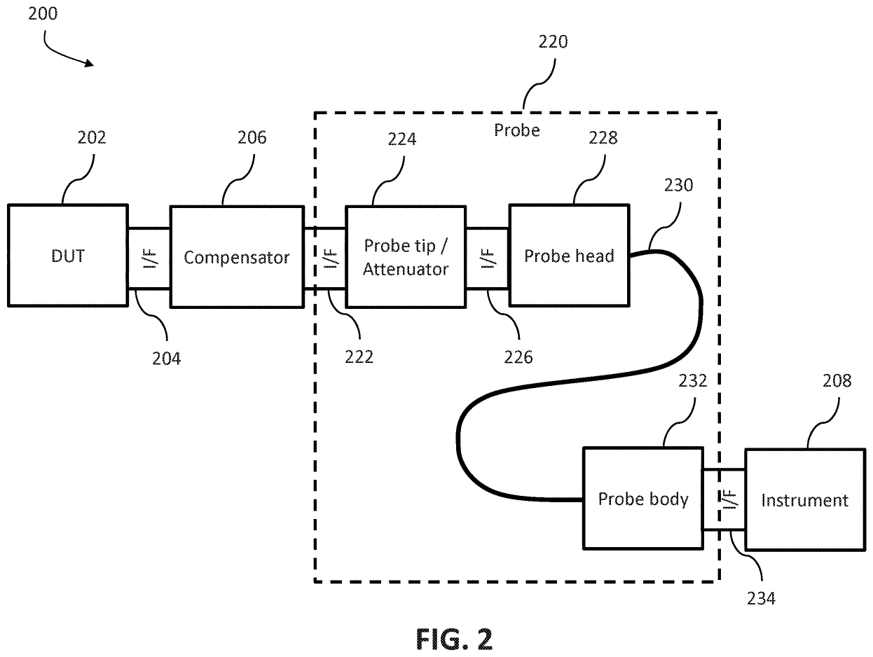

FIG. 2 is a block diagram of a testing system 200 according to embodiments of the disclosure. The testing system 200 includes a probe 220 connected between a DUT 202 and a test and measurement instrument 208, such as an oscilloscope, for example. The DUT 202 includes a current shunt which carries a current to be measured. The probe 220 is connected to the shunt to measure a voltage drop across the shunt. The voltage drop is measured by the instrument 208 which, knowing the resistance value of the shunt, calculates the current flowing through the shunt.

The probe 220 may include a probe tip/attenuator 224, a probe head 228, a probe cable 230, and a probe body 232. The probe body 232 connects to an input of the instrument 208 through connection interface 234. The probe body is connected to the probe head 228 through the probe cable 230, which is generally long, e.g. typically 1 meter, and flexible to allow the probe head 228 to be positioned physically close to the DUT. The probe head connects to the probe tip/attenuator 22 though connection interface 226. The connection interface 226 may comprise any types of mating connectors that provide sufficient bandwidth, such as, for example, SMA, USB-C, etc. Connection interface 226 allows a user of the probe to conveniently exchange the probe tip 224 with one of a number of different probe tips 224 having different attenuation values to accommodate different signal levels from the DUT. The probe tip 224 is typically shielded cable flexible enough to reach from the probe head 228 to a point on the DUT very close to the shunt to be measured. According to some embodiments, the probe 220 may include an isolation barrier to provide galvanic isolation between the DUT 202 and the instrument 208. A commercially available example of this type of probe is the TICP Series Iso Vu™ Isolated Current Probes from Tektronix.

The testing system 200, according to embodiments of the disclosure, includes a programmable compensator device 206 connected between the probe tip 224 and the shunt on the DUT 202. The compensator 206 connects to the probe tip through connection interface 222, which may comprise mating connectors of sufficient bandwidth. The compensator 206 connects to the DUT through connection interface 204. If the compensator 206 is not needed for a particular measurement use case, it can be removed by the user, and the probe tip can connect to the DUT through connection interface 22 instead.

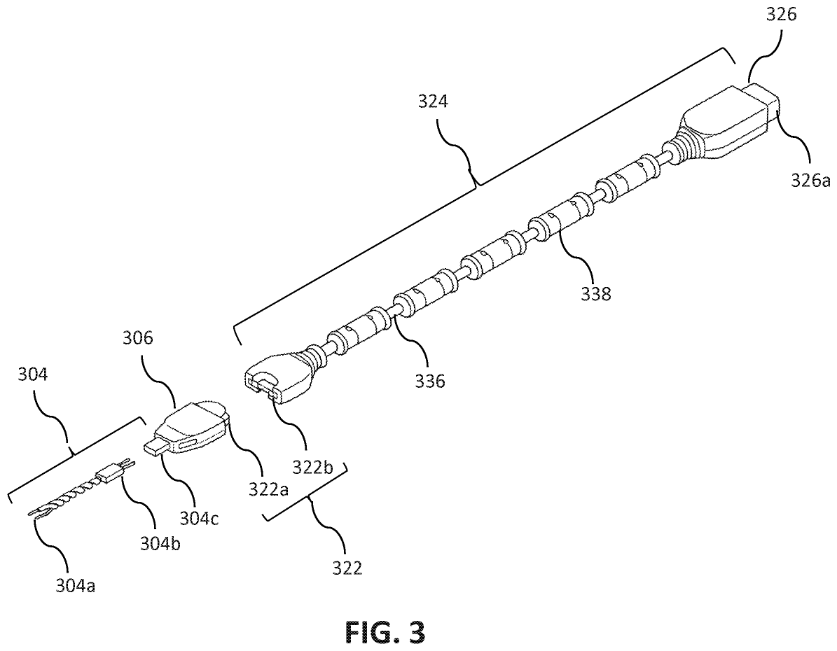

FIG. 3 is a more detailed perspective view of a probe tip and compensator device, according to an example embodiment of the disclosure. The probe tip 324 may be an example of probe tip 224 of FIG. 2. The compensator 306 may be an example of the compensator 206 of FIG. 2. Probe tip 324 connects to the probe head (not shown) through connection interface 326, which may be an example of connection interface 226 of FIG. 2. Probe tip 324 includes a portion 326a of the connection interface 326. The mating portion of connection interface 326 is located on the probe head. The probe tip 324 may include a probe tip cable 336, typically a coaxial cable, as well as one or more magnetic elements 338 to provide additional shielding to the cable. The magnetic elements are spaced apart to provide flexibility to allow the probe tip cable to bend into position in proximity of the shunt to be measured. The probe tip may also include an attenuator of a particular value (not shown).

The probe tip 324 connects to the compensator device 306 through connection interface 322, which may be an example of connection interface 222 of FIG. 2. In the example embodiment shown in FIG. 3, the connection interface 322 includes connector 322a on compensator 306, and mating connector 322b on probe tip 324. Compensator 306 connects to the DUT, through connection interface 304, which may be an example of connection interface 204 of FIG. 2. In the example embodiment shown in FIG. 3, the connection interface 304 includes a pair of twisted lead wires to be soldered, or otherwise electro-mechanically connected, at one end 304a to each side of the shunt to be measured. The connection interface 304 also includes a pin header 304b at the other end of the pair of twisted lead wires, and a mating pin socket 304c on the compensator 306. In other embodiments, the DUT may include a pin header which the pin socket 304c can connect to directly.

The compensator device 206, 306 can be tuned through programming to compensate for a wide variety of parasitic inductive responses which makes this device flexible to be used in DUTs that were not initially designed to have a shunt used for measurement. The compensating pole is individual from the DUT and able to be used for many shunts with a programming adjustment made to compensate for the individual frequency response of each shunt.

Specifically, according to some embodiments, the compensator 206, 306 increases and decreases a capacitance value in a digital capacitor. An increase in capacitance corresponds to a cutoff frequency decrease for a compensating pole (so that the compensating poll starts compensating at lower frequencies), and the converse is true: a decrease in capacitance corresponds to higher programmed cutoff frequency. According to other embodiments, the compensator 206, 306 can involve tuning a capacitor, resistor, inductor, any combination thereof, and/or all programmable and tunable components that can adjust a pole value. In some embodiments, the compensator can include tunable components that are mechanically tuned to adjust the compensating pole.

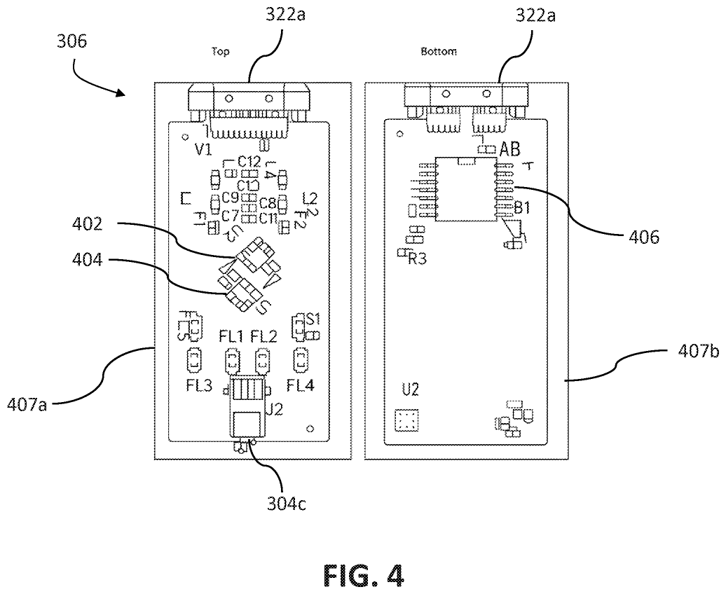

FIG. 4 shows a top side 407a and bottom side 407b printed circuit board layout of an implementation of compensator 306 according to an example embodiment of the disclosure. As shown in FIG. 4, the compensator 306 receives the signal under test from the shunt through connector 304c. The signal is passed to programmable compensation elements 402, 404, and then the compensated signal is output from the compensator at connector 322a. Programming of the programmable compensation elements 402, 404 is controlled by processor 406 which may be any kind of processor including a microprocessor, microcontroller, FPGA, ASIC, etc. The compensator 306 receives power and communication signals through connector 322a. With reference to FIG. 2, in some embodiments, power may be supplied by the test and measurement instrument 208, through probe 220, or may be supplied by the probe. In still other embodiments, power may be supplied by an external power supply, or a battery, for example. Communication signals are exchanged between the compensator 306 and either or both of the probe 220 and the instrument 208.

Some methods of picking a pole value for the compensator device based on connection to a shunt are described herein.

In some examples, the present disclosure involves methods with no vector network analyzer (VNA) equipment needed. In such examples, a source measure unit (SMU) force lead is placed on the high and low sides of the shunt, then the high side is removed. This response should look like a square step response. Any measured overshoot or undershoot can be corrected for with digital pole programming. Another way to source a square step response is using an arbitrary function generator (AFG) and/or arbitrary waveform generator (AWG) square wave, and tuning based on observed overshoot and undershoot.

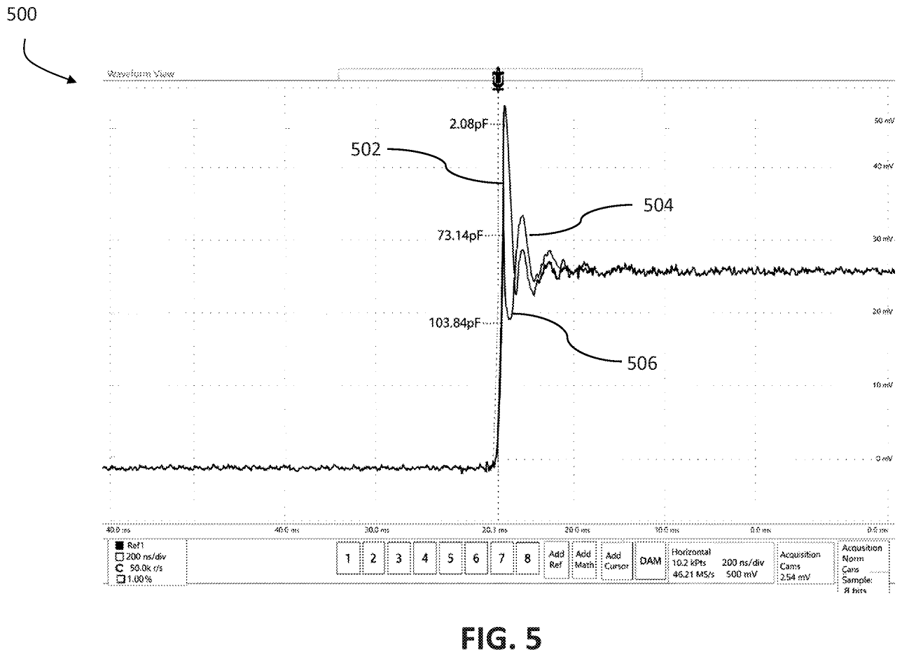

FIG. 5 is a graph 500 illustrating a three time domain responses: one having undershoot 506, one having overshoot 502, and one having a response close to a square step response 504. The capacitance values for the time domain responses are values programmed into the capacitors used for the compensating pole, but, as mentioned above, other adjustable components may also be used to tune these time domain responses. However, the user wants a square wave, so that's where the presently described device is used.

The present disclosure describes methods for tuning in digital capacitor value on the compensator device. Methods involve a binary search, in which multiple square captures are needed. Methods include using a neural network and/or function that looks at a signal and determines a capacitance value to try. In some examples, the present disclosure involves a test and measurement instrument, such as an oscilloscope, analyzing the signal and displaying the analysis results on the screen of the test and measurement instrument. Some methods involve using a test and measurement instrument math channel filter (or other software filter application method) to model the expected response of a given pole or set of poles on a signal, where the user inputs a shunt's resistance value and adjusts modeled capacitance value(s), and the test and measurement instrument determines the nearest capacitance value(s) to the modeled value(s) for use with the probe.

In some examples, these poles change per shunt and per DUT. So, the user would need to initiate a tunable component compensation program, or the user can pick a saved value for the tunable component. In some examples, the compensator device can store a tunable component value for particular scenarios from the probe coupled to the test and measurement instrument and transmit the value for storage in the test and measurement instrument. The tunable component value can be chosen dynamically within a range of values that each device provides. In such examples, the tunable component may have an upper and/or lower limit, or the tunable component may device to make several with different ranges. For example, the presently described device can provide a range of 2.0 pF to 500 pF and another range of 1 nF to 100 nF. In some examples, multiple of the compensator devices may be coupled together in series, in parallel, or in other arrangements to make more complex compensating adjustments as needed. In some examples, plug-in shunts may inform the test and measurement instrument of the correct tunable component value (e. g, digital capacitance) automatically, or the user can calculate or choose from a menu of approximations of the tunable component values.

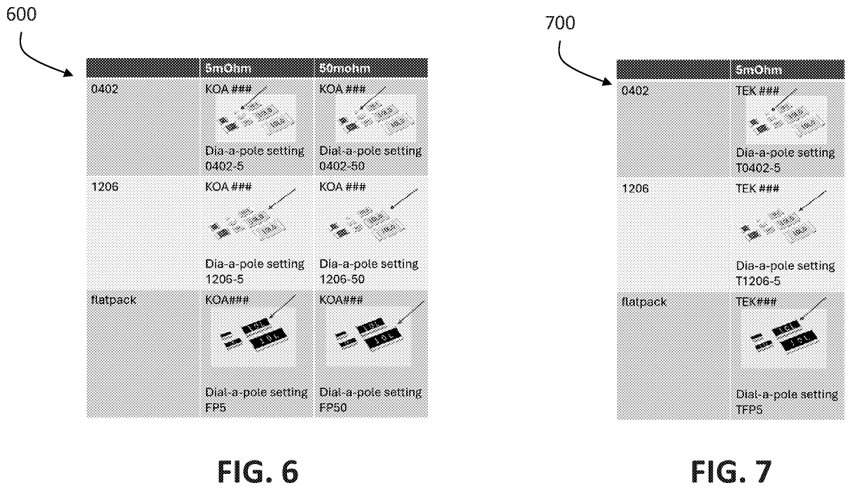

In some examples, a method for picking a pole value is to have a stored table of shunts with known compensation values as shown in FIG. 6. These shunts could be from OEMs or custom shunts. In such examples, the user can select a shunt to use in their circuit and install, or use a shunt for pick-and-place installation. In further examples, the user can connect (including solder) the presently described device to the shunt.

In some examples, a user can use reference off-the-shelf shunts in their circuit, or the user can approximate to their shunt to adjust the presently described device. This method provides an easier way to maximize high frequency performance of the probe when reading solder-in shunts.

In some examples, the compensator device may include an identifier component or chip and a capacitance digital-to-analog converter (DAC). When plugged into the probe input cable, the compensator device would tell the test and measurement instrument to provide a menu to select the shunt in use. In such examples, the user may pick the shunt using the provided table via the test and measurement instrument, and the test and measurement instrument transmits the information to the DAC to adjust the pole.

In some examples, the compensator device includes programmable circuits to perform calculations to adjust the pole, and in further examples, the programmable circuits of the compensator device can provide multiple options to fine adjust the pole.

In some examples, the present disclosure involves providing the user with reference table for custom shunts, and accordingly, the user can solder to terminals on shunt and select the shunt to set the compensator device.

In such examples, the present disclosure involves providing a table of custom shunts, as illustrated in FIG. 7, and the custom shunts can be used in a user's circuits (after solder and/or pick-and-place installation). The compensator device connects to the shunt. In some examples the custom shunt may have a connector and an identifier component as well as a communication interface back to the test and measurement instrument. In further examples, the device has an identifier chip and a cap DAC, and when plugged into the probe input cable, the device interacts with the test and measurement instrument to provide a menu for the user to select the shunt in use. After selection of the shunt by the user, the test and measurement instrument tells the DAC on the device to adjust the pole.

With reference to FIG. 2, in some embodiments, the compensator device 206 may be built-in as part of probe 220, rather than implemented as a separate accessory. For example, in some embodiments, the compensator 206 may be integrated together with the probe tip 224. In some embodiments, this may also be integrated together with the shunt itself.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

What is claimed is:

1. A compensation device for a test and measurement probe, comprising:
a first connection interface structured to receive an uncompensated measurement signal from a shunt on a device under test (DUT);
one or more adjustable compensation elements in a compensation circuit, the one or more adjustable compensation elements configured to produce a compensated measurement signal by adjusting a frequency response pole of the compensation circuit to compensate for an inductance of the shunt; and
a second connection interface structured to output the compensated measurement signal to the test and measurement probe.

2. The compensation device of claim 1, wherein at least one of the one or more adjustable compensation elements is selected from the group consisting of a capacitor, a resistor, and an inductor.

3. The compensation device of claim 1, wherein the compensation circuit comprises one of an RC filter or an L over R filter.

4. The compensation device of claim 1, wherein at least one adjustable compensation element of the one or more adjustable compensation elements is digitally programmable.

5. The compensation device of claim 4, wherein the at least one adjustable compensation element is a digital capacitor.

6. The compensation device of claim 4, further comprising a processor configured to control the programming of the at least one adjustable compensation element.

7. The compensation device of claim 1, further comprising one or more communication signal lines for exchanging communication signals between the compensation device and one or more of the test and measurement probe and a test and measurement instrument.

8. The compensation device of claim 7, further comprising an identifier component to allow the test and measurement probe or the test and measurement instrument to identify the specific compensation device.

9. The compensation device of claim 1, wherein the first connection interface comprises a pin connector.

10. The compensation device of claim 9, wherein the first connection interface further comprises a pair of twisted lead wires to be soldered to the ends of the shunt.

11. The compensation device of claim 1, wherein the first connection interface and the second connection interface are structured to allow multiple compensation devices to be cascaded together in series or in parallel.

12. A test and measurement system, comprising:
a test and measurement instrument;
a shunt having a known resistance value and a frequency-dependent inductance, the shunt structured to be inserted into a current path on a device under test (DUT);
a compensation circuit configured to receive an uncompensated measurement signal from the shunt and output a compensated measurement signal; and
a test and measurement probe to convey the compensated measurement signal to an input of the test and measurement instrument.

13. The test and measurement system of claim 12, wherein the compensation circuit includes one or more adjustable compensation elements configured to produce the compensated measurement signal by adjusting a frequency response pole of the compensation circuit to compensate for the frequency-dependent inductance of the shunt.

14. The test and measurement system of claim 13, wherein the compensation circuit comprises one of an RC filter or an L over R filter.

15. The test and measurement system of claim 13, wherein at least one adjustable compensation element of the one or more adjustable compensation elements is digitally programmable.

16. The test and measurement system of claim 12, further comprising one or more communication signal lines for exchanging communication signals between the compensation circuit and the test and measurement instrument.

17. The test and measurement system of claim 16, wherein the test and measurement instrument includes one or more processors and a display, the one or more processors configured to execute code that causes the one or more processors to, display a user interface on the display, the user interface including a table of shunts with known compensation values.

18. The test and measurement system of claim 17, wherein the user interface allows a user to select a particular shunt from the table, and wherein the one or more processors are further configured to cause the compensation circuit to adjust the frequency response pole to the known compensation value for the particular shunt.

19. The test and measurement system of claim 16, wherein the shunt has a known compensation value and includes an identifier component, and wherein the one or more processors are further configured to read the identifier component from the shunt and cause the compensation circuit to adjust the frequency response pole to the known compensation value for the shunt.

20. The test and measurement system of claim 12, wherein the compensation circuit is integrated into the test and measurement probe.
